(19) United States
(12) Patent Application Publication
(10) Pub. No.: US 2010/0263999 A1
(43) Pub. Date: Oct. 21, 2010

(54) LOW-COST PROCESS-INDEPENDENT RF MEMS SWITCH

(76) Inventors: Dimitrios Peroulis, West Lafayette, IN (US); Adam Fruehling, West Lafayette, IN (US)

Correspondence Address: BAHRET & ASSOCIATES, 320 NORTH MERIDIAN STREET, SUITE 510, INDIANAPOLIS, IN, 46204, US

(21) Appl. No.: 12/808,002

(22) PCT Filed: Dec. 15, 2008
(86) PCT No.: PCT/US08/86897

§ 371 Date: Jun. 14, 2010

Related U.S. Application Data
(60) Provisional application No. 61/013,537, filed on Dec. 13, 2007.

(51) Int. Cl. H01H 59/00; H01L 21/30

(52) U.S. Cl. 200/181; 438/52; 257/E21.211

(57) ABSTRACT

A radio frequency (RF) micro-electro-mechanical systems (MEMS) switch and high yield manufacturing method. The switch can be fabricated with very high yield despite the high variability of the manufacturing process parameters. The switch is fabricated with monocrystalline material, e.g., silicon, as the moving portion. The switch fabrication process is compatible with CMOS electronics fabricated on Silicon-on-Insulator (SOI) substrates. The switch comprises a movable portion having conductive portion selectively positioned with a bias voltage to conductively bridge a gap in a signal line.

### CROSS-REFERENCE TO RELATED APPLICATION

This application claims the benefit of Provisional Patent Application No. 61/013,537, filed Dec. 13, 2007, which application is hereby incorporated by reference along with patent application Ser. No. 11/963,071, filed Dec. 21, 2007.

### BACKGROUND OF THE INVENTION

This invention relates to micro-electromechanical systems (MEMS) and, more particularly, MEMS switches.

Radio frequency MEMS technology has been under development for nearly two decades now. In this technology, integrated circuits are fabricated with miniaturized mechanical moving parts (e.g., beams and plates) that can be actuated in a variety of ways including electrostatically, magnetically, electrothermally, piezoelectrically and others. The induced mechanical movement reconfigures the electrical circuitry and thus provides additional functionality. Typical devices produced by this methodology include RF switches and variable capacitors that can be applied to reconfigurable filters, antennas, and matching networks to name a few examples. RF MEMS switches are dominant devices in this technology because they provide the maximum possible adaptability. While reconfigurability can also be achieved with solid-state switches (diodes and transistors), RF MEMS switches offer many significant advantages including low loss, ultra-low power consumption, high isolation, and ultra-high linearity.

Unlike conventional MEMS inertia sensors (accelerometers and gyroscopes), which have now become commercially available, RF MEMS switches face significant challenges to enter the commercial world. They only began to be commercially available in about 2005. Conventional solid-state switches have inferior performance, but they are generally cheaper, and the pricing makes the conventional solid-state switches more attractive than the RF MEMS switches. This difference in price is not explained by the inherent cost of the manufacturing processes, since they are similar. The price difference is attributed to low manufacturing yield of RF MEMS switches.

This low manufacturing yield is largely due to a single factor: high process variability. Unlike the CMOS industry that uses dedicated tools tuned for only one function, the production paradigm is very different for the RF MEMS industry. The RF MEMS industry is significantly smaller in volume and therefore cannot afford to have dedicated foundries and processes for each process and each device. Instead, most RF MEMS companies utilize general foundries, of which there are approximately 25 around the world. These foundries use the same tools to fabricate products for their various customer. These products can vary widely including switches, optical mirrors, infrared sensors and bio-sensors. However, high-yield manufacturing requires a different assembly line for each product with well-characterized and well-tuned tools that only produce that particular product without being contaminated with foreign films and processes. This is not possible for many of these devices because of their low commercial volume. Consequently, they need to be manufactured with common tools that suffer from great process variations.

There exists a need for a MEMS switch, and particularly an RF MEMS switch, that exhibits more repeatable electrical and mechanical performance than heretofore possible. A related need exists for an RF MEMS switch that can be cost-effectively produced with very high yield.

### SUMMARY OF THE INVENTION

The present invention provides a MEMS switch comprising a stationary portion having a first electrical contact and a monocrystalline movable portion having a second electrical contact on an end thereof. The monocrystalline movable portion is operatively positioned relative to the stationary portion such that the first electrical contact is connected to the second electrical contact in a closed state of the MEMS switch and disconnected from the second electrical contact in an open state of the MEMS switch.

Another aspect of the invention is a method of fabricating a MEMS switch, starting with a silicon-on-insulator wafer having a device layer. The method includes patterning the shape of a movable structure on the device layer; depositing and patterning a conductive contact material on a portion of the movable structure using optical lithography techniques to form a switch structure; depositing and patterning a sacrificial layer; depositing and patterning a conductive signal line having a gap portion selectively bridged by the contact material; depositing and patterning a biasing layer to span a portion of the movable structure and to control the switch structure with an electrostatic force; selectively etching the sacrificial layer to avoid obstructing the movable structure; and etching the oxide layer of the wafer to release the movable structure.

A general object of the present invention is to provide an improved MEMS switch and a process for manufacturing the switch.

A further object is to provide a MEMS switch that can be manufactured with very high yield despite high variability of process parameters. For, example, embodiments of the present invention have properties including one or more of actuation voltage, contact resistance, and residual stress that are essentially independent of the specific fabrication parameters of the foundry producing the device, such that the properties do not vary significantly from die to die, wafer to wafer, lot to lot, or even foundry to foundry.

Other objects and advantages of the present invention will be more apparent upon reading the following detailed description in conjunction with the accompanying drawings.

### BRIEF DESCRIPTION OF THE DRAWINGS

FIG. 1 illustrates a MEMS switch.

FIG. 2 shows a measured and calculated pull-in voltages for SOI cantilevers.

FIG. 3 illustrates a sample fabrication process for SOI MEMS device.

FIG. 4 shows a measured on state performance.

FIG. 5 shows a measured off state performance.

FIG. 6 shows a measured on switching speed.

FIG. 7 shows a measured off switching speed.

FIG. 8 illustrates a diagram of a monocrystalline MEMS switch.

FIG. 9 shows a SE overview of a switched CPW line with a SEM inset detail of a switch contact.

FIG. 10 shows a SEM view of a MEMS switch contact.

FIG. 11 shows a magnified image of patterned beam with contact metal deposited and patterned corresponding to FIG. 3-B in the fabrication process.

FIG. 12 shows a magnified image of patterned beam with contact and patterned sacrificial layer corresponding to FIG. 3-C in the fabrication process.

FIG. 13 shows a magnified image of patterned lines suspended above unreleased switches corresponding to FIG. 3-D in the fabrication process.

FIG. 14 shows a magnified overview image of completed switch structure corresponding to FIG. 3-D in the fabrication process.

FIG. 15 shows a magnified image of patterned and released beam without previous layers deposited corresponding to FIG. 3-F in the fabrication process.

FIG. 16 illustrates a top view of an HFSS drawing of a switch structure.

FIG. 17 illustrates a three-dimensional view of a MEMS switch.

FIG. 18. illustrates the long term bias stability versus time for different cantilever materials in air.

FIG. 19 illustrates a full-wave simulation of switch on-state return loss.

FIG. 20 illustrates a full-wave simulation of switch on-state insertion loss

FIG. 21 shows an HFSS simulation plot of return loss from 1 mm switched CPW on SOL

FIG. 22 shows an HFSS simulation plot of insertion loss from 1 mm switched CPW on SOL

FIG. 23 illustrates a DC ohmic contact switch.

FIG. 24 shows a SEM of DC ohmic contact switch.

### DETAILED DESCRIPTION OF PREFERRED EMBODIMENTS

For the purpose of promoting an understanding of the principles of the invention, reference will now be made to the embodiments illustrated in the drawings and specific language will be used to describe the same. It will nevertheless be understood that no limitation of the scope of the invention is thereby intended, such alterations and further modifications in the illustrated device and such further applications of the principles of the invention as illustrated therein being contemplated as would normally occur to one skilled in the art to which the invention relates.

The present invention provides a new MEMS switch design that is substantially independent of most or all of the aforementioned process variability. This MEMS switch preferably has a moving part made of undoped monocrystalline silicon. Its monocrystalline nature renders this material among the purest available with significant fewer defects than any other material available in the integrated circuit industry. In addition, undoped monocrystalline silicon has insignificant variability in its material properties, allowing the MEMS designer to know them a priori. The moving part can also be made of other monocrystalline materials and may be in the form of a cantilever beam, fixed-fixed beam, a plate, or a combination. The nonmoving part also has the same variations depending on the moving part.

The fabrication process of the RF MEMS switch is also compatible with CMOS electronics fabricated on Silicon-on-Insulator (SOI) substrates. Both the RF circuitry and the switch actuators are fabricated on a single SOI substrate.

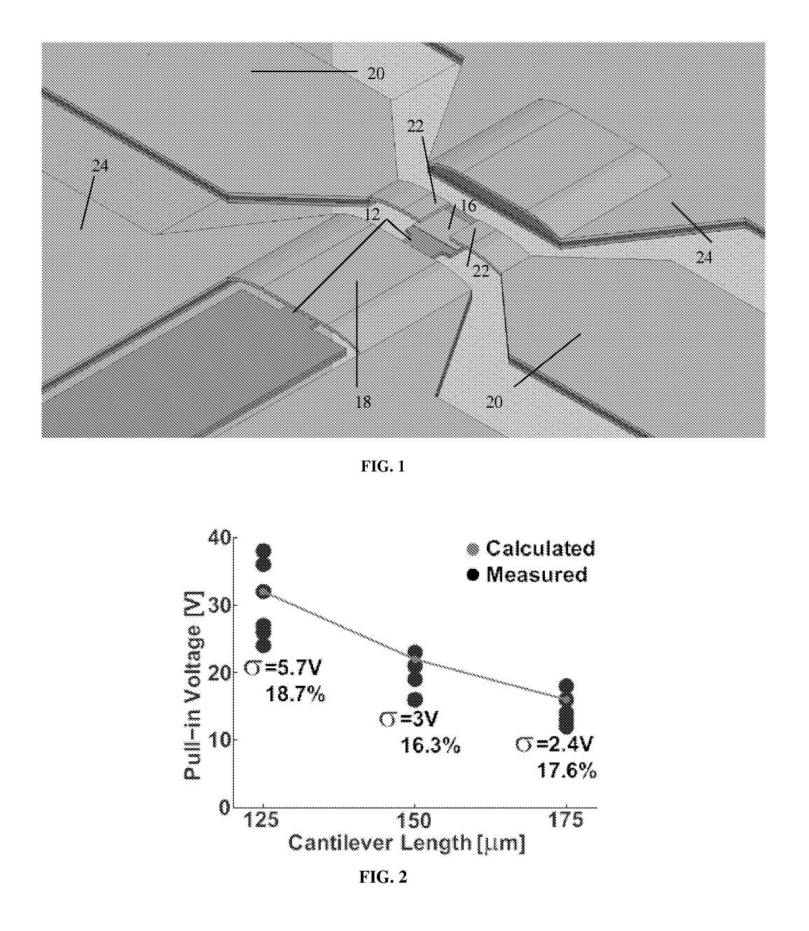

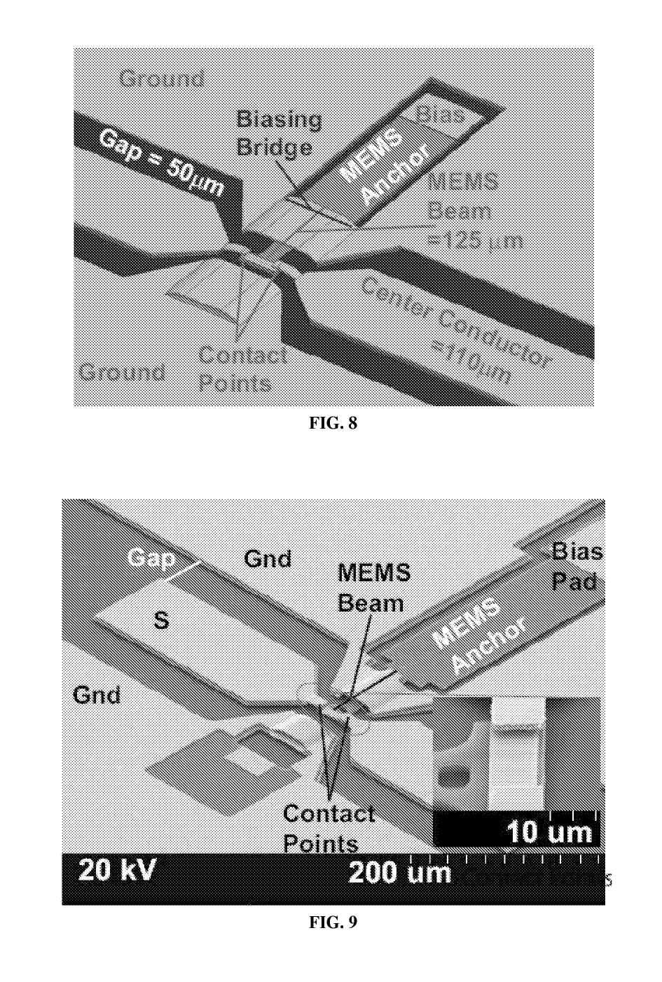

FIG. 1 illustrates a switch according to a first embodiment of the present invention. The disclosed embodiment contains a 2 μm thick single-crystal silicon cantilever beam 12, a 2 μm thick discontinuous gold coplanar waveguide (CPW) line 20 and a 2 μm thick gold biasing electrode illustrated in FIG. 8. The ground planes 24 of the CPW are separated from center line conductor 20 by a gap distance of about 50 μm. The gap distance narrows to 20 μm at the switch. The contact areas 22 of the discontinuous CPW line 20 are suspended approximately 2.5 μm above the silicon cantilever beam 12. The switch is normally fabricated open (off state). The center conductor of the CPW line 20 is discontinuous in this state and the switch offers a high isolation. The silicon beam is coated with a 0.5 μm gold film 16 at the contact area. While this particular implementation utilizes gold-to-gold contacts, other contact materials can readily be used to form the signal line, bias, and contact portions without affecting the structural integrity of the switch. Other metals such as aluminum, copper, and the like are suitable.

When a voltage is applied between the biasing electrode and the silicon beam 12, the beam deflects upward making contact with the contact portion 22 of the discontinuous CPW line 20. When the beam is deflected the gold foil 16 provides a conductive bridge between the discontinuous CPW line 20 segments and the switch is closed (on state).

The pull-in voltage (V_{PI}) required to deflect the beam in the MEMS switch can be determined with the equation

$${V}_{PI} = \sqrt{\frac{8 {k}_{Beam} {g}^{3}}{27 {ε}_{0} A}}$$

where A is the actuation area, g is the gap between the beam and biasing structure in the neutral position, ∈₀ is the permittivity constant of free space, and k_{Beam} is the spring constant of the beam. Assuming a nearly uniform electrostatic force on the cantilever beam, the spring constant (k_{Beam}) is determined with equation

$${k}_{Beam} = \frac{2 Ew}{3} {( \frac{t}{l} )}^{3}$$

where E is Young's modulus of the material, w is the width, t is the thickness, l is the length of the beam.

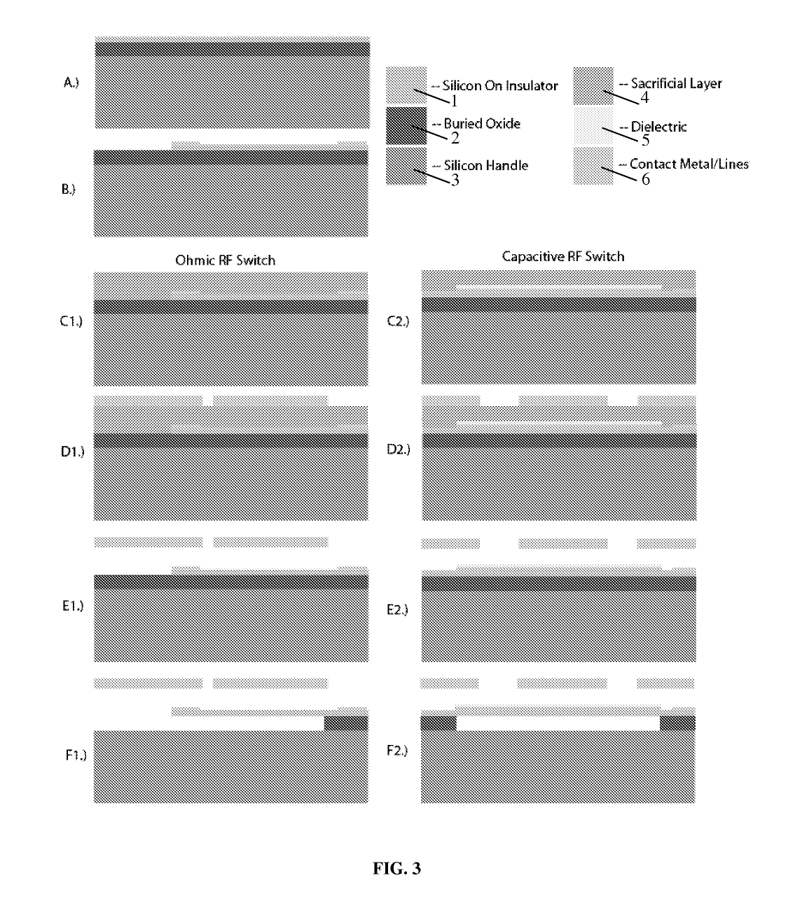

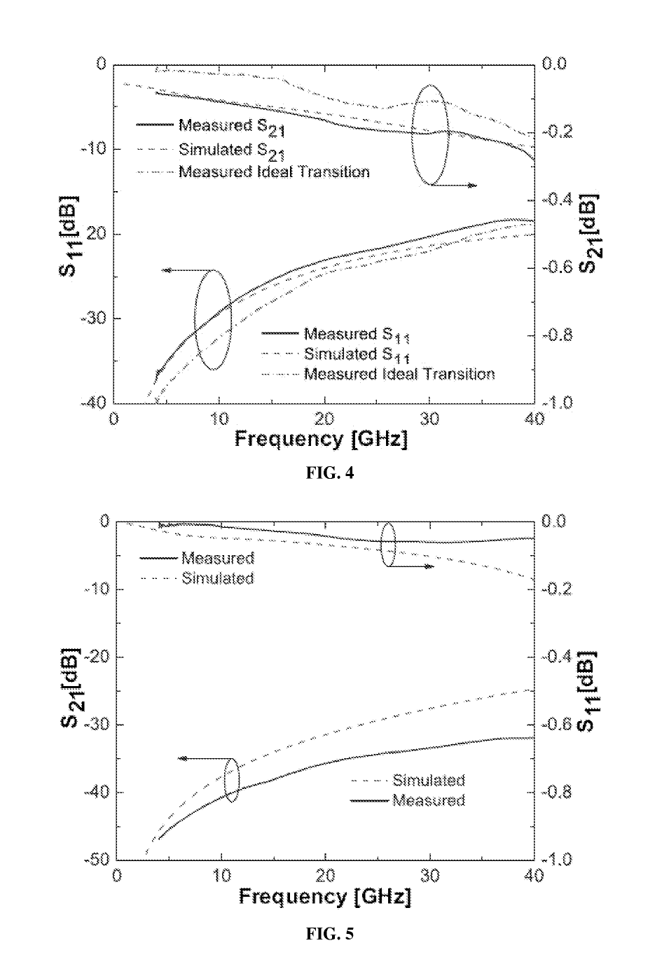

FIG. 2 shows the calculated pull-in voltage as a function of the cantilever length where the width and thickness of the cantilever beam are 20 μm and 2 μm, respectively. FIG. 4 also shows the measured pull-in voltages for these devices. Five theoretically identical beams are measured for beam lengths of 125 μm, 150 μm, and 175 μm. The mean pull-in voltage values and standard deviations for the cantilevers of lengths of 125 μm, 150 μm, and 175 μm are (30.5 V, 18.7%), (18.5 V, 16.3%) and (13.3 V, 17.6%) respectively. These deviations can attributed to thickness variations of just 0.25 μm from the center to the edge of the wafer. This variation is prescribed by the wafer's manufacturer due to uneven polishing of the SOI device layer.

The pull-in voltage variation can be significantly reduced by more careful polishing in a production environment and by using CMOS-grade SOI wafers. As shown in FIG. 1, the biasing structure 18 is stiffer than the beam 12 and has a typical beam to biasing spring constant ratio of 1:50. The metal structures of the biasing structure are deposited with tensile stress, and any variation in stress of the deposited film during fabrication serves only to stiffen the biasing structure as can be seen in the biasing structure spring constant (k_{Biasing}) equation

$${k}_{Biasing} = 32 {Ew ( \frac{t}{l} )}^{3} + 8 σ ( 1 - v ) w ( \frac{t}{l} )$$

where, σ is the residual stress, and v is the Poisson ratio of the material.

The restoring force and the contact force will vary depending on the application and design of the MEMS switch. The restoring force (Fᵣ) is determined with the equation

Fᵣ=k(g−gₒₙ)

and contact force (F_{c}) is determined with the equation

$${F}_{c} = {ε}_{0} {A ( \frac{{V}_{Actuation}}{2 {g}_{on}} )}^{2}$$

where V_{Actuation} is the applied switch bias, and gₒₙ is the separation between the MEMS device and the biasing pad in the on state. The applied switch bias V_{Actuation} may be higher than the pull-in voltage V_{PI} to achieve the desired contact force value. The secrificial layer thickness and the operating voltage can be varied as needed for the desired restoring force and the contact force of the specific application.

The mechanical design parameters for an embodiment of this application are summarized in Table I. The suspended CPW cantilevers that extend over the end of the switch are approximately, 25 μm×15 μm×2 μm (L×W×T) to ensure a rigid structure for high contact force and to minimize the effects of any fabrication stresses that might tend to curl the beam.

TABLE I
SWITCH PARAMETERS

| Parameter | Value |
|---|---|
| Length [μm] | 65, 125 |
| Width [μm] | 20 |
| Thickness [μm] | 2 |
| k_{Beam} [N/m] | 50, 7 |
| V_{PI} [V] | 117, 32 |
| Switching Speed (ON) [μs] - fastest | 3.6 |
| Switching Speed (OFF) [ns] - fastest | 600 |
| Contact Force [μN] | 125, 18 |
| Restoring Force [μN] | 111, 16 |

An embodiment of MEMS switch has a SOI device layer resistivity of 3-5 Ω-cm and handle layer resistivity of 2 kΩ-cm. This compromise in RF losses is necessary in order to minimize charging phenomena on the SOI layer. Significant charging was observed when high-resistivity SOI beams were employed. The RF performance penalty by the low-resistivity SOI layer is minimized by etching the device and oxide layers except for anchoring of the metal lines. The CPW transition length, where the center conductor of the CPW narrows, and separation width between discontinuous CPW center conductor segments can be minimized to reduce losses and loading due to the switch. The dimensions of an embodiment of a 50Ω switched CPW are summarized in Table II.

TABLE II
RF DESIGN DIMENSIONS

| Parameter | Value |
|---|---|
| CPW center conductor [μm] | 110 |
| CPW gap [μm] | 50 |
| Transition Length [μm] | 50 |
| CPW center conductor at switch [μm] | 15 |
| CPW gap at switch [μm] | 20 |
| Separateion between CPW segments [μm] | 25 |
| Separation between CPW and switch [μm] | 2.5 |

The main challenge in using undoped monocrystalline silicon as the structural moving part of a MEMS switch is its very high RF loss. Therefore, careful RF design and fabrication process flow are needed for a successful device.

FIG. 3 shows a presently preferred fabrication process. The developed fabrication process has been used to design an RF MEMS switch suitable for operating from DC to 100 GHz. The switch can be fabricated using Silicon-On-Insulator (SOI) CMOS electronics. The fabrication process can yield both metal-to-metal contact switches and metal-to-dielectric contact switches. The metal-to-metal switch is well suited for the 0-60 GHz range, and the metal-to-dielectric switch is well suited to the 10-100 GHz range.

The process begins with a bare SOI wafer having of silicon on insulator 1, a buried oxide layer 2, and a silicon handle 3 as shown in FIG. 3-A.

The wafer is patterned using positive photolithography techniques. The precursor for the movable structure is formed from the silicon on insulator layer 1, also known as the device layer. The device layer beam is patterned and reactive ion etched using SF₆ plasma. KOH may also be used as an etchant to remove a portion of the silicon on insulator layer 1 so that the part that will become the movable portion is shaped. RF contacts lines 6 are deposited and patterned using photolithography and etching as shown in FIG. 3-B.

The fabrication process can vary depending on whether an ohmic or a capacitive switch is fabricated. In the ohmic switch fabrication process, a sacrificial layer 4 is deposited and patterned as shown in FIG. 3-C1. Using positive resist, the sacrificial layer is patterned and baked. The sacrificial layer can be a dielectric layer and provides rigid support for additional layers. The sacrificial layer 4 fills the void created by the removal of a portion of the silicon on insulator layer 1. The sacrificial layer 4 provides a foundation on which a second set of contact metal lines 6 is deposited and provides a physical separation of the second set of contact metal lines 6 from the first set of contact metal lines 6. This step can be repeated multiple times as needed to achieve both a rigid and removable structures.

The second set of contact metal lines 6 comprises the signal line and the biasing pad. The signal line and the biasing structure are deposited on the sacrificial layer as shown in FIG. 3-D1. The signal lines and biasing structure are deposited and anchored to non-beam portions of the device layer silicon or they may be anchored to the buried oxide layer. The signal line may be a CPW, microstrip, stripline, slotline, including the asymmetric versions of each, or other signal lines that conduct RF current.

The sacrificial layer 4 is etched and removed as shown in FIG. 3-E1 to allow the beam to move toward the biasing pad. The sacrificial layer may be removed with a hot positive resist stripper release.

The oxide layer 2 is etched and the cantilever portion of the beam is released as shown in FIG. 3-F1. A hafnium dip to etch the buried oxide layer and to release the beam may be used.

If a capacitive switch is desired, a modified fabrication process is implemented following the process illustrated in 3-B. A capacitive switch contains a dielectric layer 5 and a sacrificial layer 4 as illustrated in FIG. 3-C2. The dielectric 5 is patterned with the movable portion and will remain coupled to the moveable portion. The dielectric and the sacrificial layer are deposited and patterned as described for the process of fabricating the ohmic switch.

The lines and biasing layer are deposited on top of the sacrificial layer and dielectric layer as shown in 3-D2. The lines and biasing structures may be anchored to isolated device layer silicon or to the buried oxide layer.

The sacrificial layer 4 is etched and removed as shown in FIG. 3-E2 to allow the movable portion to move toward the biasing pad. The sacrificial layer may be removed with a hot positive resist stripper release.

The oxide layer 2 is etched and the movable portion released from the oxide substrate as shown in FIG. 3-F2. A hafnium dip to etch the buried oxide layer and to release the beam may be used.

RF measurements of an embodiment of the preferred MEMS switch are performed on an Agilent E8361C with an on-wafer calibration kit using 2.4 mm cables and probes. The switch exhibits the desired insertion loss of less than 0.29 dB up to 40 GHz corresponding to a contact resistance of approximately 0.5Ω per contact with two contacts made in the exemplary switch configuration. The isolation is greater than 30 dB up to 40 GHz. This corresponds to an off-state equivalent capacitance of approximately 1.8 fF by curve fitting.

Simulations indicate that the device is capable of much higher frequency operation, however measurements were limited by the use of 2.4 mm components. Measurement results in the on and off states are shown in FIG. 4 and FIG. 5 respectively. In DC operation, embodiments of the disclosed SOI switches have operated for more than 93 million hot cycles (switch current limited to about 200 μA) in open air maintaining consistent pull-in voltages and contact resistances until end of life. Contact resistances of less than 0.5Ω have been measured for bias voltages less than 1.25 V_{PI}.

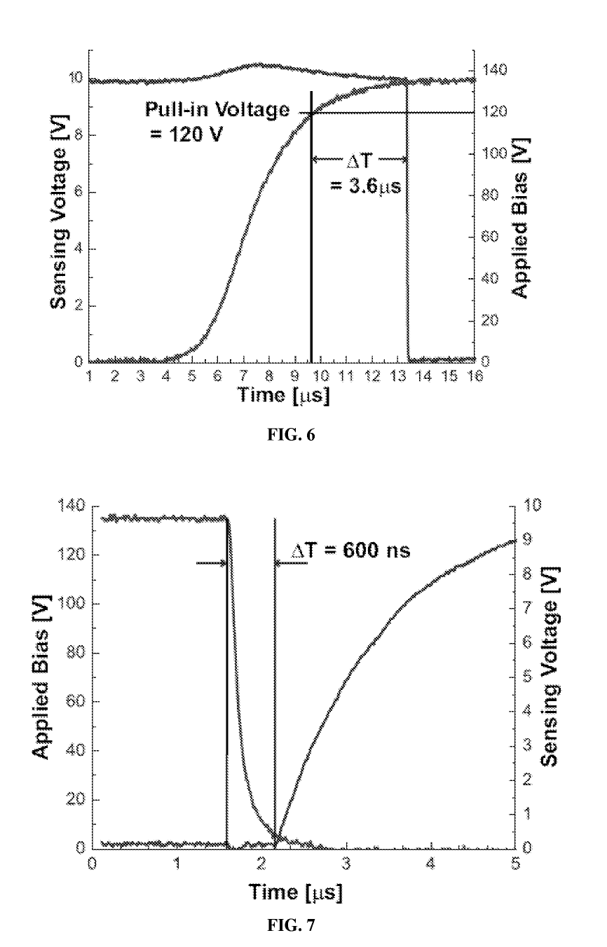

Switching for the shortest devices has been measured at less than 4 μs for the on state, and 600 ns for the off state, as shown in FIG. 6 and FIG. 7, respectively.

FIG. 8 shows a diagram of the monocrystalline MEMS switch. In the illustrated embodiment the center line conductor is 110 μm wide and is separated from the ground plane by a distance of 50 μm, but the gap narrows as the center conductor of the CPW tapers to the contact point.

FIG. 9 shows a SE overview of a switched CPW line with a SEM inset detail of a switch contact.

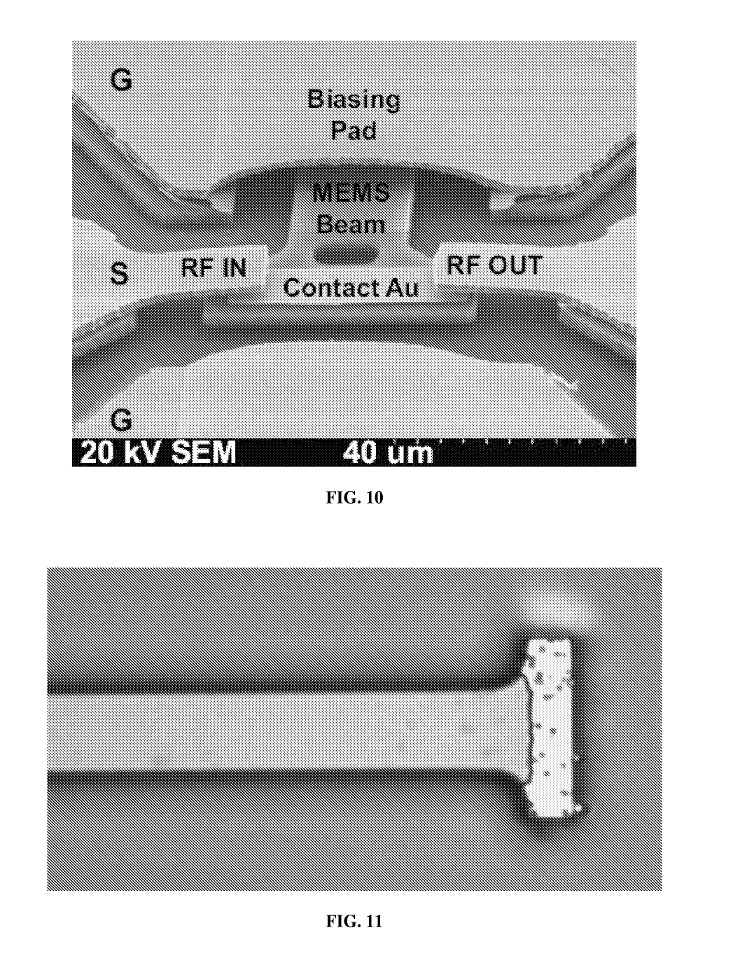

FIG. 10 shows a SEM view of a MEMS switch contact.

FIG. 11 shows a magnified image of patterned beam with contact metal deposited and patterned corresponding to FIG. 3 B in the fabrication process.

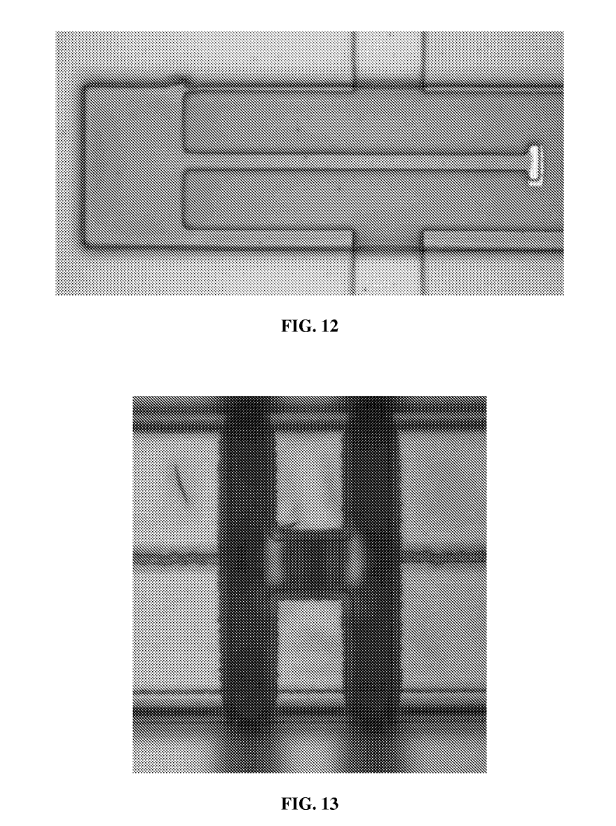

FIG. 12 shows a magnified image of patterned beam with contact and patterned sacrificial layer corresponding to FIG. 3C in the fabrication process.

FIG. 13 shows a magnified image of patterned lines suspended above unreleased switches corresponding to FIG. 3D in the fabrication process.

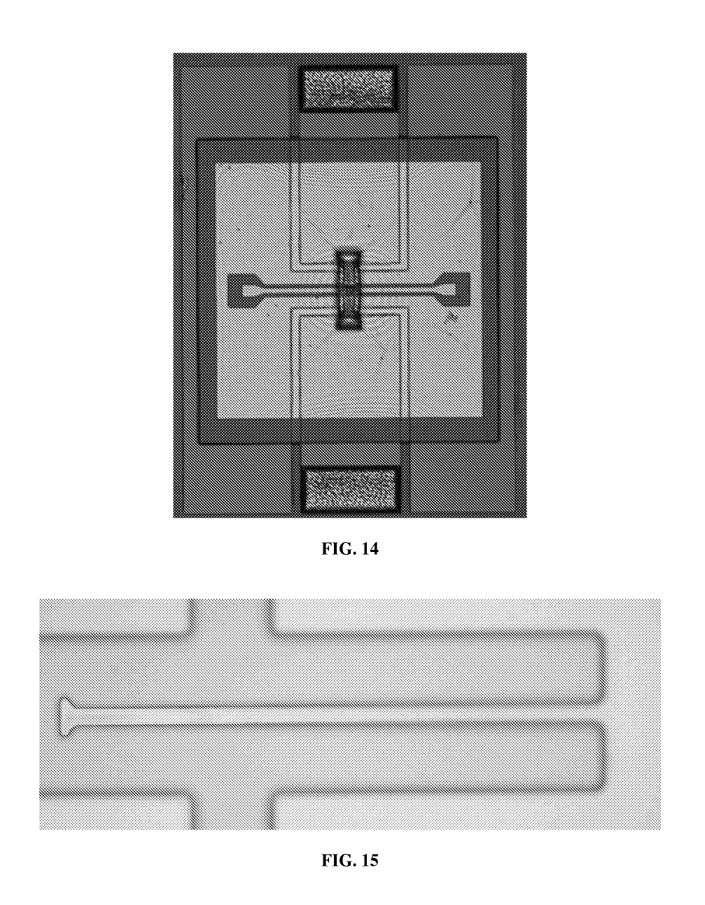

FIG. 14 shows a magnified overview image of completed switch structure corresponding to FIG. 3D in the fabrication process.

FIG. 15 shows a magnified image of patterned and released beam without previous layers deposited corresponding to FIG. 3F in the fabrication process.

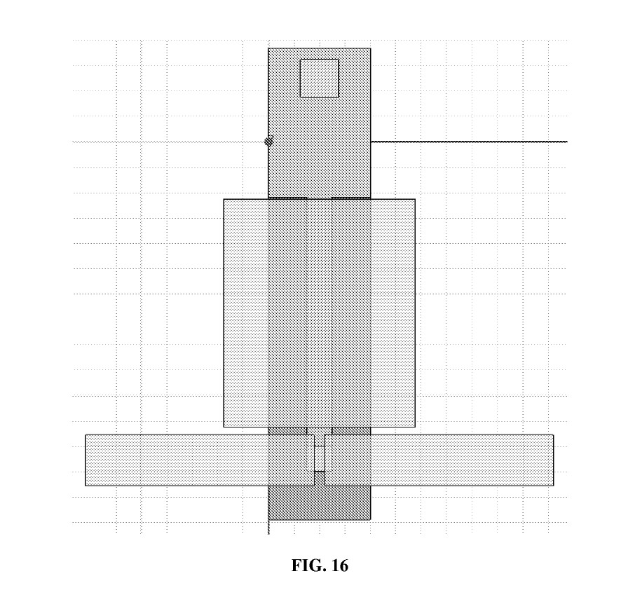

FIG. 16 illustrates a top view of an HFSS drawing of a switch structure.

FIG. 17 illustrates a three-dimensional view of a MEMS switch.

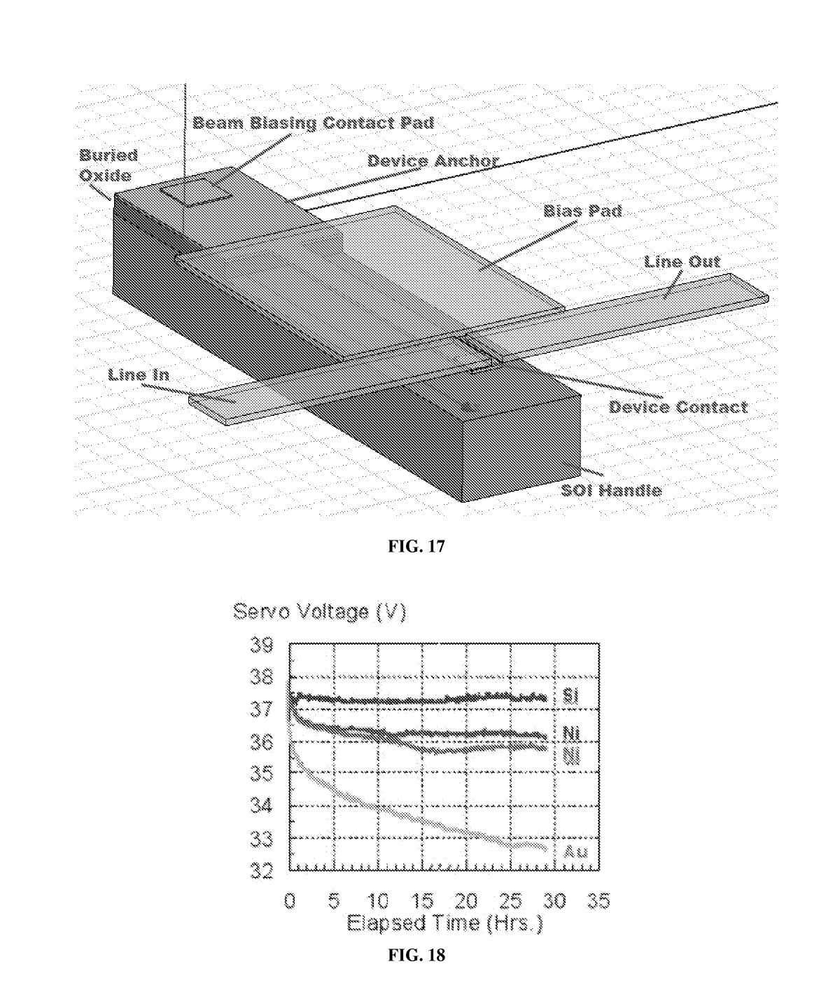

FIG. 18. illustrates the long term bias stability versus time for different cantilever materials in air.

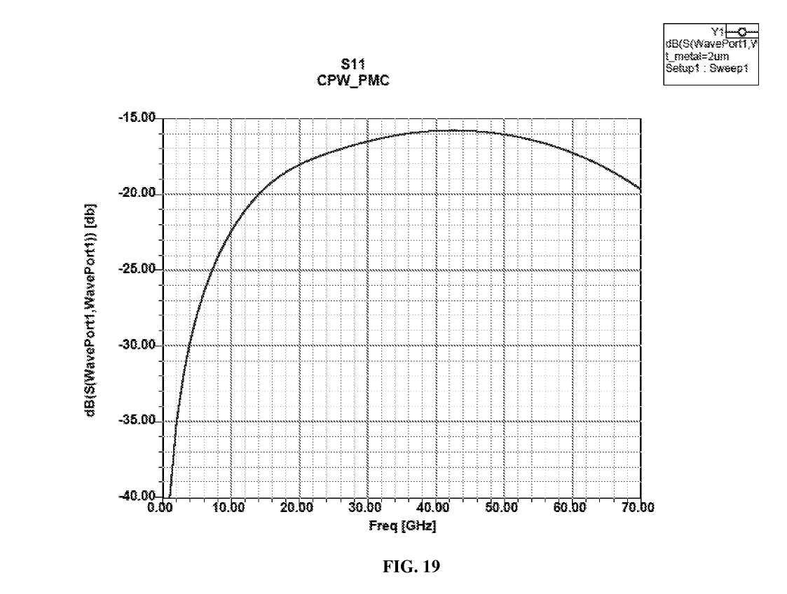

FIG. 19 illustrates a full-wave simulation of switch on-state return loss.

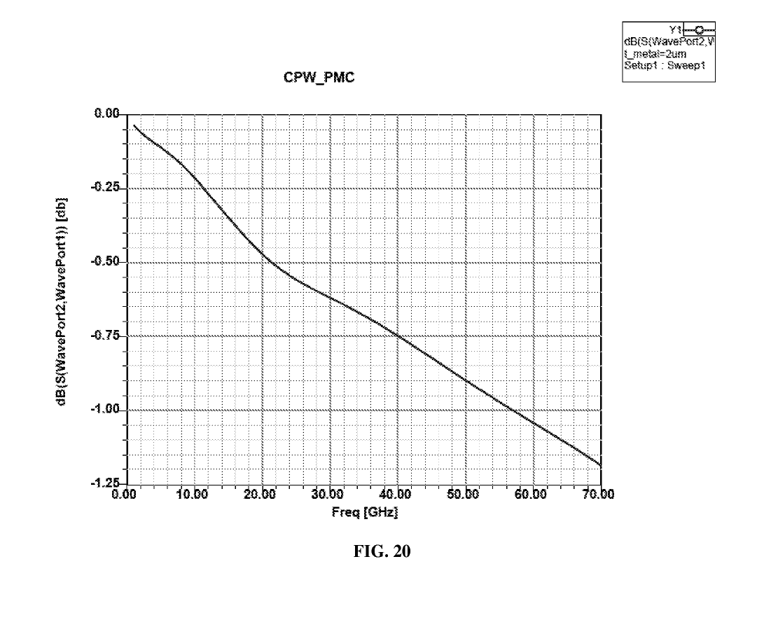

FIG. 20 illustrates a full-wave simulation of switch on-state insertion loss

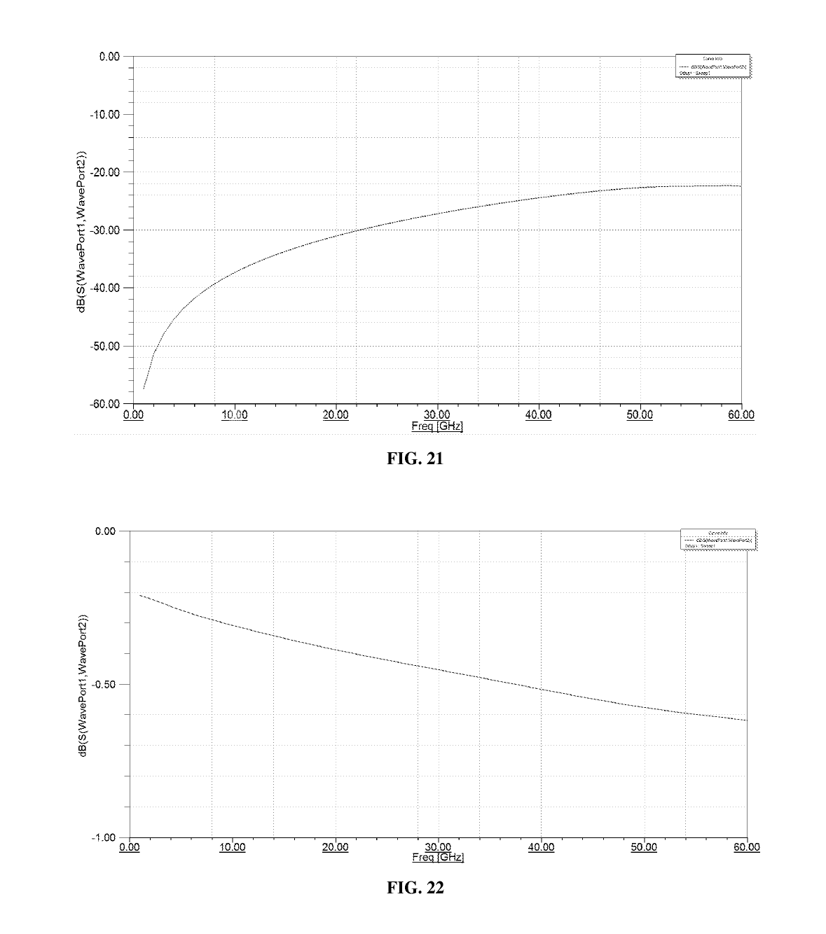

FIG. 21 shows an HFSS simulation plot of return loss from 1 mm switched CPW on SOL

FIG. 22 shows an HFSS simulation plot of insertion loss from 1 mm switched CPW on SOL

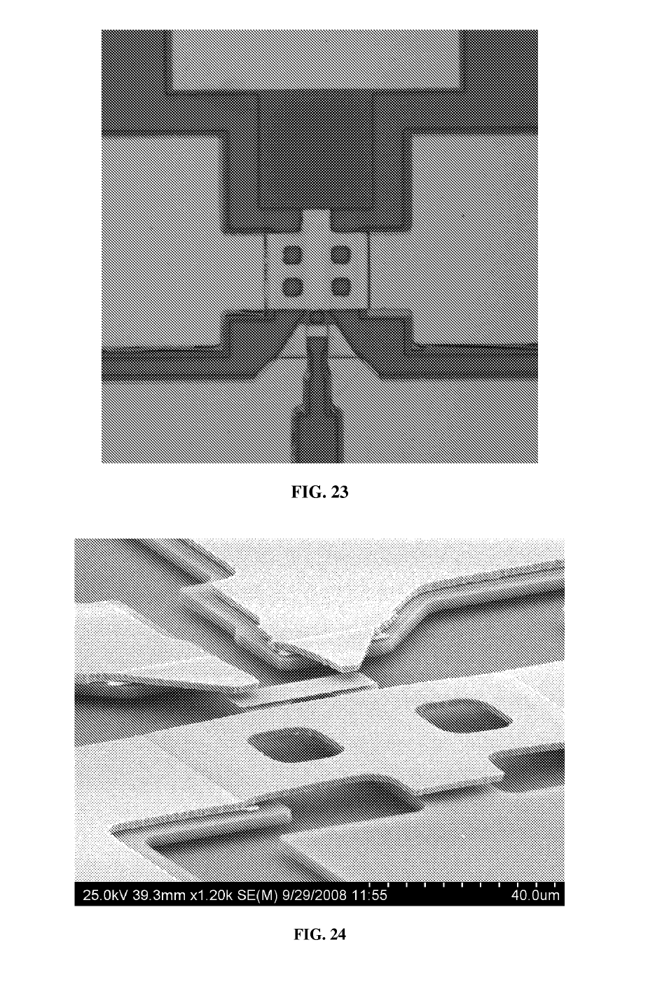

FIG. 23 illustrates a DC ohmic contact switch.

FIG. 24 shows a SEM of DC ohmic contact switch.

While the invention has been illustrated and described in detail in the drawings and foregoing description, the same is to be considered as illustrative and not restrictive in character, it being understood that only preferred embodiments have been shown and described and that all changes and modifications that come within the spirit of the invention are desired to be protected.

We claim:

1. A MEMS switch, comprising:
a monocrystalline device layer;
a base layer;
a buried oxide layer between and coupled to both said device layer and said base layer; and
a first electrical contact that is stationary with respect to said base layer;
wherein a portion of said device layer is movable with respect to said base layer, said movable portion having a second electrical contact formed thereon from a material different than said monocrystalline device layer and operatively positioned relative to said first electrical contact such that said first electrical contact is connected to said second electrical contact in a closed state of said MEMS switch and disconnected from said second electrical contact in an open state of said MEMS switch.

2. The MEMS switch of claim 1, wherein said movable portion includes an elongate member.

3. The MEMS switch of claim 2, wherein said elongate member is monocrystalline silicon.

4. The MEMS switch of claim 3, further comprising a third electrical contact that is stationary with respect to said base layer and operatively positioned relative to said movable portion such that said first and third electrical contacts are interconnected by said second electrical contact in said closed state of said MEMS switch and disconnected from each other in said open state of said MEMS switch.

5. The MEMS switch of claim 4, wherein each of said first and third contacts is connected to an RF signal conductor.

6. The MEMS switch of claim 5, further comprising means for electrostatically actuating said movable portion.

7. The MEMS switch of claim 6, wherein said electrostatic actuating means includes an electrical bias member adjacent to said movable portion.

8. The MEMS switch of claim 7, wherein said electrical bias member is a bridge across said movable portion.

9. The MEMS switch of claim 8, wherein said elongate member of said movable portion is a cantilever beam.

10. The MEMS switch of claim 9, wherein said RF signal conductors are coplanar waveguides.

11. A method of fabricating a MEMS switch, comprising:
providing a silicon-on-insulator wafer having a monocrystalline silicon device layer, a buried oxide layer and a base layer;
patterning the shape of a movable structure on said device layer;
depositing and patterning a conductive contact material on a portion of said movable structure using optical lithography techniques to form a switch structure;
depositing and patterning a conductive signal line having a gap portion selectively bridged by said contact material;
depositing and patterning a biasing layer to span a portion of said movable structure and to control said movable structure with an electrostatic force; and
etching said oxide layer of said wafer to release said movable structure.

12. The method of claim 11, wherein said movable structure is between said signal line and said base layer.

13. The method of claim 11, wherein said movable structure is deflected away from said base layer and towards said signal line upon application of said electrostatic force.

14. The MEMS switch of claim 1, wherein said movable portion is oriented a greater distance from said base layer in said closed state compared to the distance of said movable portion from said base layer in said open state.

15. The MEMS switch of claim 1, wherein said movable portion is between said first electrical contact and said base layer.

16. A SOI wafer configured as a MEMS switch, comprising:
a monocrystalline device layer made of a first material;
an electrically insulating base layer;
a buried oxide layer between and coupled to said device layer and said base layer;
a first electrical contact coupled to a movable portion of said device layer and formed of a second material different than said first material; and
a second electrical contact stationary with respect to said base layer and operatively positioned such that said first electrical contact is connected to said second electrical contact in a closed state of said MEMS switch and disconnected from said second electrical contact in an open state of said MEMS switch, said second electrical contact separated from said base layer,
wherein said first electrical contact is oriented between said second electrical contact and said base layer and wherein a portion of said SOI wafer is intact.

17. The MEMS switch of claim 16, wherein said movable portion is oriented a greater distance from said base layer in said closed state than in said open state

18. The MEMS switch of claim 16, further comprising a signal line deposited on said device layer and electrically coupled to said second electrical contact.

19. The MEMS switch of claim 16, further comprising a signal line deposited on said buried oxide layer and electrically coupled to said second electrical contact.
